(19) United States
(12) Patent Application Publication
(10) Pub. No.: US 2026/0209544 A1
(43) Pub. Date: Jul. 23, 2026

(54) RESIN COMPOSITION FOR FORMING PHASE-SEPARATED STRUCTURE, METHOD FOR PRODUCING STRUCTURE HAVING PHASE-SEPARATED STRUCTURE, AND A BLOCK COPOLYMER

(71) Applicants: TOKYO OHKA KOGYO CO., LTD., Kawasaki-shi (JP); Institute of Science Tokyo, Tokyo (JP)

(72) Inventors: Ryutaro SUGAWARA, Kawasaki-shi (JP); Takehiro SESHIMO, Kawasaki-shi (JP); Takahiro DAZAI, Kawasaki-shi (JP); Teruaki HAYAKAWA, Tokyo (JP); Shinsuke MAEKAWA, Tokyo (JP)

(21) Appl. No.: 19/454,805

(22) Filed: Jan. 21, 2026

(30) Foreign Application Priority Data
Jan. 23, 2025 (JP) 2025-009845

(51) Int. Cl. C09D 153/00; C08F 297/02

(52) U.S. Cl. CPC C09D 153/00; C08F 297/026

(57) ABSTRACT

A resin composition for forming a phase-separated structure having excellent vertical orientation and etching resistance. The resin composition contains a block copolymer (A) having blocks (A1), (A2), and (A3) in this order, the block (A1) includes a polymer having a repeating structure of a constituent unit represented by formula (a1; the block (A2) includes a polymer having a constituent unit represented by formula (a2-1; and the block (A3) includes a random copolymer having a structure in which a constituent unit represented by formula (a3-1) and a constituent unit represented by formula (a3-2) are randomly arranged. In the formula (a2-1), R^{a21} is a substituent having a silicon atom

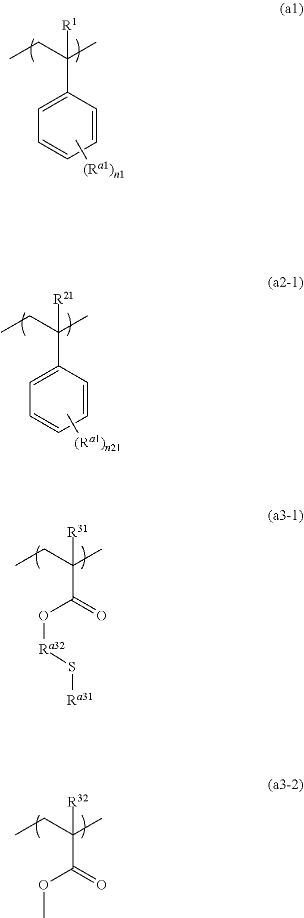

### RELATED APPLICATIONS

This application claims priority to Japanese Patent Application No. 2025-009845, filed Jan. 23, 2025, the entire content of which is incorporated herein by reference.

### BACKGROUND OF THE INVENTION

### Field of the Invention

The present invention relates to a resin composition for forming a phase-separated structure, a method for producing a structure having a phase-separated structure, and a block copolymer.

### Related Art

In recent years, following further miniaturization of a large-scale integrated circuit (LSI), a technique for processing a finer structure has been demanded. For such a demand, a technique has been developed for forming a finer pattern utilizing a phase-separated structure formed by self-organization of a block copolymer in which blocks incompatible with each other are bonded (see, for example, Patent Document 1).

The above-mentioned block copolymer undergoes separation (phase-separation) on a microscale due to repulsion between mutually incompatible blocks, and forms a structure with a regular periodic structure by heat treatment or the like. Specifically, the periodic structure may be cylindrical (columnar), lamellar (plate-like), or spheric (spherical).

In order to utilize the phase-separated structure of the block copolymer, it is essential for a self-organized nanostructure formed by microphase separation to be formed only in a specific region and oriented in a desired direction. In order to control a position and orientation of the nanostructure as described above, processes such as graphoepitaxy for controlling a phase separation pattern by a guide pattern and chemical epitaxy for controlling a phase separation pattern based on a difference in a chemical state of a substrate have been proposed.

The block copolymer forms a structure having a regular periodic structure by phase separation. The phrase “structural period” means a period of a phase structure observed when a structure having a phase-separated structure is formed and refers to a sum of lengths of phases incompatible with each other. In a case where a phase-separated structure forms a cylindrical structure perpendicular to a surface of a substrate, a structural period (L₀) is a distance between centers (pitch) of two adjacent cylindrical structures.

It has been known that a structural period (L₀) is determined by inherent polymerization properties such as a degree of polymerization N and the Flory-Huggins interaction parameter χ. That is, the larger the product “χ·N” of χ and N, the greater the mutual repulsion between different blocks in the block copolymer becomes. Therefore, in the case of χ·N>10.5 (hereinafter, referred to as “intensity separation limit”), repulsion between different blocks in the block copolymer is large, leading to a stronger tendency to cause phase separation. Accordingly, at the intensity separation limit, the structural period is approximately N^{2/3}·χ^{1/6} and a relationship of the following expression (1) is satisfied. That is, the structural period is proportional to the degree of polymerization N, which correlates with a molecular weight and a molecular weight ratio between different blocks.

$${L}_{0} ∝ a \cdot {N}^{2 / 3} \cdot {χ}^{1 / 6} \qquad ( 1 )$$

wherein L₀ denotes a structural period;
a is a parameter indicating a size of a monomer;
N denotes a degree of polymerization; and
χ is an interaction parameter, and a higher value means higher phase separation performance.

Accordingly, the structural period (L₀) can be controlled by adjusting a composition and a total molecular weight of a block copolymer. Therefore, in order to form a structure having a smaller L₀ by utilizing a phase-separated structure formed by self-organization of a block copolymer, a method of decreasing a molecular weight of the block copolymer is considered. However, when the molecular weight of the block copolymer is simply reduced, the degree of polymerization (N) is lowered, which may cause a problem that phase separation does not occur. Thus, there is a demand for a material having a large interaction parameter (χ) (High χ material) so that phase separation occurs even when the molecular weight of the block copolymer is reduced.
Patent Document 1: Japanese Unexamined Patent Application, Publication No. 2008-36491

### SUMMARY OF THE INVENTION

In order to form a fine pattern by utilizing a phase-separated structure formed by self-organization of a block copolymer, it is preferable that the phase-separated structure formed by the block copolymer has a vertical orientation. However, generally known High X materials hardly exhibit vertical orientation.

In addition, when a layer having a fine pattern formed therein is used as a mask for substrate processing, a material having etching resistance is required.

The present invention has been made in view of the above circumstances, and an object of the present invention is to provide a resin composition for forming a phase-separated structure capable of forming a phase-separated structure having excellent vertical orientation and etching resistance, a method for producing a structure having a phase-separated structure using the same, and a block copolymer for use in the resin composition for forming a phase-separated structure.

As a result of the inventors' extensive studies to solve the above problem, the present invention has been completed based on findings that the above object can be solved if a particular block copolymer (A) is used. Specifically, the present invention provides the following aspects.

A first aspect relates to a resin composition for forming a phase-separated structure, the resin composition containing a block copolymer (A),
the block copolymer (A) having a block (A1), a block (A2), and a block (A3) in this order,
the block (A1) being composed of a polymer having a repeating structure of a constituent unit represented by the following formula (a1),
the block (A2) being composed of a polymer having a constituent unit represented by the following formula (a2-1), and
the block (A3) being composed of a random copolymer having a structure in which a constituent unit represented by the following formula (a3-1) and a constituent unit represented by the following formula (a3-2) are randomly arranged,

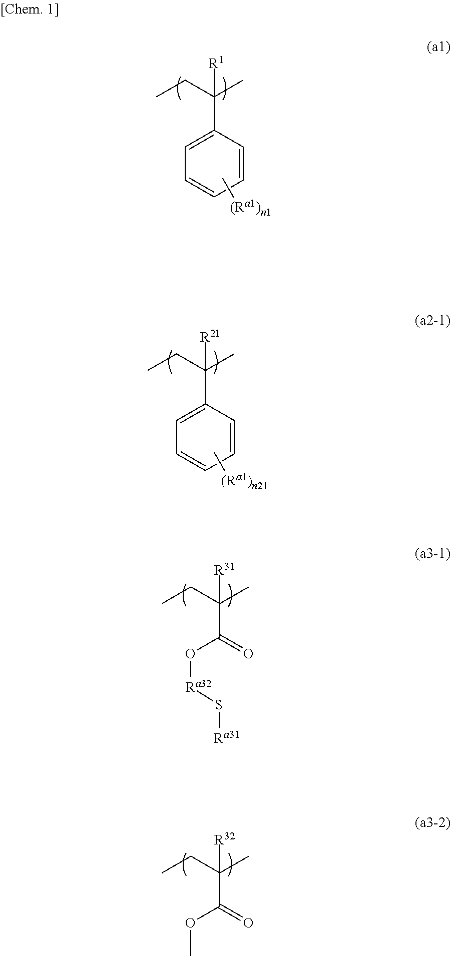

in which, in the formula (a1), Rai is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which optionally has a silyl group, a fluorine atom, a carboxy group, an amino group, a hydroxy group, or a phosphoric acid group, and R^{a32} is an alkylene group which optionally has a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.

A second aspect relates to a method for producing a structure having a phase-separated structure, the method including applying the resin composition for forming a phase-separated structure as described in the first aspect on a support to form a layer containing the block copolymer; and phase-separating the layer containing the block copolymer.

A third aspect relates to a block copolymer having a block (A1), a block (A2), and a block (A3) in this order, the block (A1) being composed of a polymer having a repeating structure of a constituent unit represented by the following formula (a1),
the block (A2) being composed of a polymer having a constituent unit represented by the following formula (a2-1),
the block (A3) being composed of a random copolymer having a structure in which a constituent unit represented by the following formula (a3-1) and a constituent unit represented by the following formula (a3-2) are randomly arranged,

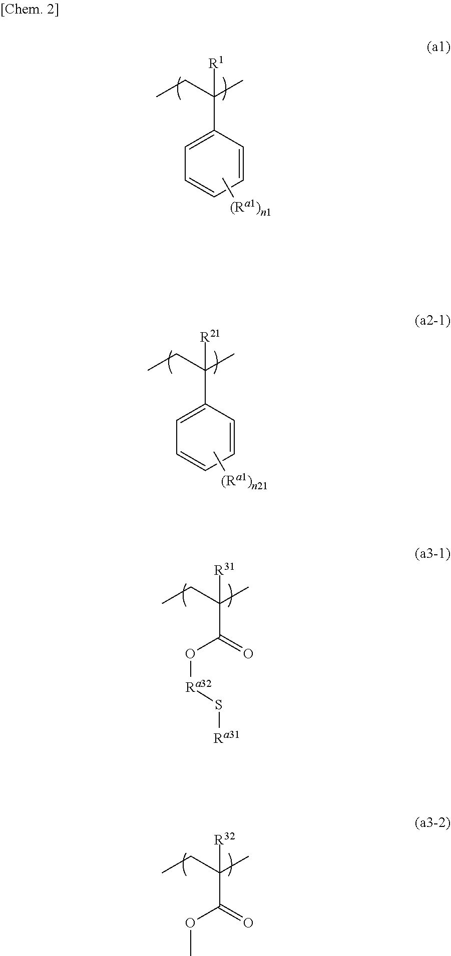

in which, in the formula (a1), R^{a1} is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which may have a silyl group, a fluorine atom, a carboxy group, an amino group, a hydroxy group, or a phosphoric acid group, and R^{a32} is an alkylene group which may have a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.

According to the present invention, it is possible to provide a resin composition for forming a phase-separated structure capable of forming a phase-separated structure having excellent vertical orientation and etching resistance, a method for producing a structure having a phase-separated structure using the same, and a block copolymer for use in the resin composition for forming a phase-separated structure.

### BRIEF DESCRIPTION OF THE DRAWINGS

FIG. 1 is a schematic process diagram illustrating an exemplary embodiment of a method for producing a structure having a phase-separated structure, and

FIG. 2 is a diagram illustrating an exemplary embodiment of an optional step.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

### <<Resin Composition for Forming Phase-Separated Structure>>

A resin composition for forming a phase-separated structure according to the first aspect contains a block copolymer (A). The block copolymer (A) has a block (A1), block (A2), and a block (A3) in this order. The block (A1) is composed of a polymer having a repeating structure of a constituent unit represented by formula (a1). The block (A2) is composed of a polymer having a constituent unit represented by formula (a2-1). The block (A3) is composed of a random copolymer having a structure in which a constituent unit represented by formula (a3-1) and a constituent unit represented by formula (a3-2) are randomly arranged.

### <Block Copolymer (A)>

The block copolymer (A) has a block (A1), block (A2), and a block (A3) in this order.

### [Block (A1)]

The block (A1) is composed of a polymer having a repeating structure of a constituent unit represented by the following formula (a1).

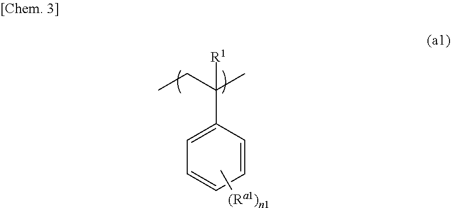

In the formula (a1), R^{a1} is an alkyl group, and n1 is an integer of 0 or more and 5 or less, and R¹ is a hydrogen atom, an alkyl group having 1 or more and 5 or less carbon atoms, or a halogenated alkyl group having 1 or more and 5 or less carbon atoms.

When n1 is an integer of 2 or more, a plurality of R^{a1}s may be same as or different from each other.

The number of carbon atoms in the alkyl group as R^{a1} is preferably 1 or more and 5 or less. Examples of the alkyl group as R^{a1} include a methyl group, an ethyl group, an n-propyl group, an isopropyl group, an n-butyl group, a sec-butyl group, an isobutyl group, and a tert-butyl group.

n1 is preferably 0 or 1, and more preferably 0.

Examples of the alkyl group having 1 or more and 5 or less carbon atoms as R¹ include a methyl group, an ethyl group, a propyl group, an isopropyl group, an n-butyl group, a sec-butyl group, a tert-butyl group, an n-pentyl group, a neopentyl group, an isopentyl group, a sec-pentyl group, a 3-pentyl group, and a tert-pentyl group. The halogenated alkyl group having 1 or more and 5 or less carbon atoms as R¹ is a group in which a portion or all of hydrogen atoms in the alkyl group having 1 or more and 5 or less carbon atoms is substituted with a halogen atom. The halogen atom is particularly preferably a fluorine atom.

R¹ is preferably a hydrogen atom or an alkyl group having 1 or more and 5 or less carbon atoms, more preferably a hydrogen atom or a methyl group, and further preferably a hydrogen atom.

### [Block (A2)]

The block (A2) is composed of a polymer having a constituent unit represented by the following formula (a2-1). Since the block (A2) has a silicon atom, excellent etching resistance is achieved.

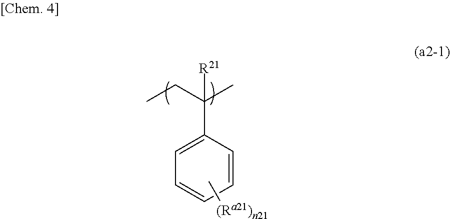

In the formula (a2-1), R^{a21} is a substituent having a silicon atom, and n21 is an integer of 1 or more and 5 or less, and R²¹ is a hydrogen atom, an alkyl group having 1 or more and 5 or less carbon atoms, or a halogenated alkyl group having 1 or more and 5 or less carbon atoms.

(Constituent Unit Represented by Formula (a2-1))

When n21 is an integer of 2 or more, a plurality of R^{a21}s may be same as or different from each other.

n21 is preferably 1.

The number of silicon atoms included in the substituent as R^{a21} is preferably 1 or more and 10 or less, more preferably 1 or more and 5 or less, and further preferably 1. The number of carbon atoms of the substituent as R^{a21} is preferably 1 or more and 30 or less, more preferably 1 or more and 20 or less, and further preferably 1 or more and 10 or less.

The substituent as R^{a21} is preferably a group represented by the following formula (a2-1-1).

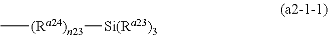

In the formula (a2-1-1), each R^{a23} is independently an organic group, R^{a24} is an oxygen atom, or an alkylene group having 1 or more and 4 or less carbon atoms, and n23 is 0 or 1.

Examples of the organic group as R^{a23} include a monovalent hydrocarbon group, alkoxy group, a group represented by —N(R^{a25})₂, and a group represented by the following formula (a2-1-2). In the formula, R^{a25} is an alkyl group. R^{a23} is preferably a monovalent hydrocarbon group.

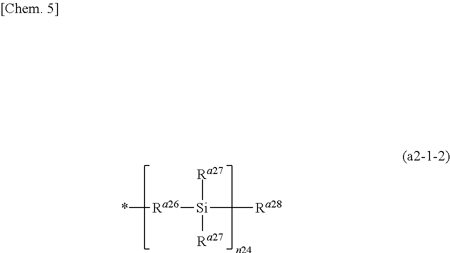

In the formula (a2-1-2), R^{a26} is a single bond or an alkylene group, R^{a27} is each independently an alkyl group, R^{a28} is an alkyl group, n24 is an integer of 1 or more and 5 or less, and * is a bond.

The monovalent hydrocarbon group as R^{a23} may be an aliphatic hydrocarbon group or an aromatic hydrocarbon group, and may be a group composed of a combination of an aliphatic hydrocarbon group and an aromatic hydrocarbon group, and is preferably an aliphatic hydrocarbon group. The number of carbon atoms in the aliphatic hydrocarbon group is preferably 1 or more and 10 or less, more preferably 1 or more and 5 or less, and further preferably 1 or more and 3 or less. Examples of the aliphatic hydrocarbon group include an alkyl group and an alkenyl group, and an alkyl group is preferable. The alkyl group may be linear or branched. Examples of the alkyl group include a methyl group, an ethyl group, an n-propyl group, an isopropyl group, an n-butyl group, an isobutyl group, a sec-butyl group, and a tert-butyl group. The aromatic hydrocarbon group is a group solely composed of an aromatic hydrocarbon ring, or a group in which two or more aromatic hydrocarbon rings are linked through a single bond. The aromatic hydrocarbon ring may be monocyclic ring, or a fused ring in which two or more rings are fused. The number of carbon atoms in the aromatic hydrocarbon group is preferably 6 or more and 20 or less, and more preferably 6 or more and 12 or less. Examples of the aromatic hydrocarbon group include a phenyl group, a naphthyl group, an anthryl group, a phenanthryl group, and a biphenyl group.

The number of carbon atoms in the alkoxy group as R^{a23} is preferably 1 or more and 10 or less, and more preferably 1 or more and 5 or less. An alkyl group in the alkoxy group may be linear or branched. Examples of the alkyl group in the alkoxy group may be the same as those listed for the alkyl groups described in relation to the monovalent hydrocarbon group as R^{a23}.

The number of carbon atoms in the alkyl group as R^{a25} is preferably 1 or more and 10 or less, more preferably 1 or more and 5 or less, and further preferably 1 or more and 3 or less. The alkyl group may be linear or branched. Examples of the alkyl group include a methyl group, an ethyl group, an n-propyl group, an isopropyl group, an n-butyl group, an isobutyl group, a sec-butyl group, and a tert-butyl group.

The number of carbon atoms in the alkylene group as R^{a26} is preferably 1 or more and 10 or less, more preferably 1 or more and 5 or less, and further preferably 1 or more and 3 or less. The alkylene group may be linear or branched. Examples of the alkylene group include a methylene group, an ethane-1,2-diyl group, a propane-1,3-diyl group, and a butane-1,4-diyl group.

The number of carbon atoms in the alkyl group as R^{a27} is preferably 1 or more and 10 or less, more preferably 1 or more and 5 or less, and further preferably 1 or more and 3 or less. The alkyl group may be linear or branched. Examples of the alkyl group include a methyl group, an ethyl group, an n-propyl group, an isopropyl group, an n-butyl group, an isobutyl group, a sec-butyl group, and a tert-butyl group.

The number of carbon atoms in the alkyl group as R^{a28} is preferably 1 or more and 10 or less, more preferably 1 or more and 5 or less, and further preferably 1 or more and 3 or less. The alkyl group may be linear or branched. Examples of the alkyl group include a methyl group, an ethyl group, an n-propyl group, an isopropyl group, an n-butyl group, an isobutyl group, a sec-butyl group, and a tert-butyl group.

n24 is preferably an integer of 1 or more and 3 or less.

Examples of the alkylene group as R^{a24} include a methylene group, an ethane-1,2-diyl group, a propane-1,3-diyl group, and a butane-1,4-diyl group.

R^{a24} is preferably an oxygen atom.

n23 is preferably 0.

Examples of the alkyl group having 1 or more and 5 or less carbon atoms and the halogenated alkyl group having 1 or more and 5 or less carbon atoms as R²¹ may be the same as those listed for these groups as R¹. R²¹ is preferably a hydrogen atom or an alkyl group having 1 or more and 5 or less carbon atoms, more preferably a hydrogen atom or a methyl group, and further preferably a hydrogen atom.

Specific examples of the constituent unit represented by the formula (a2-1) are shown below.

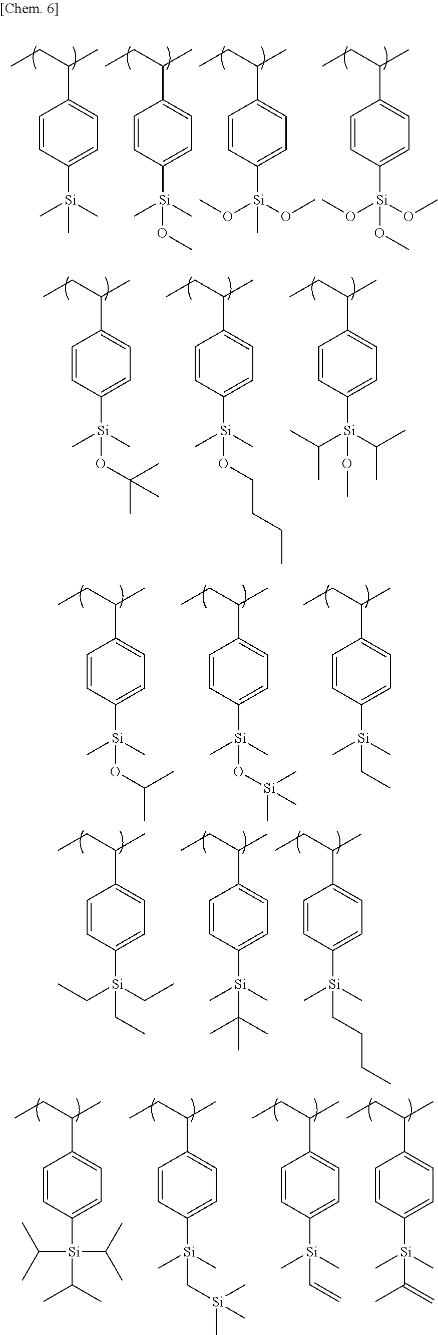

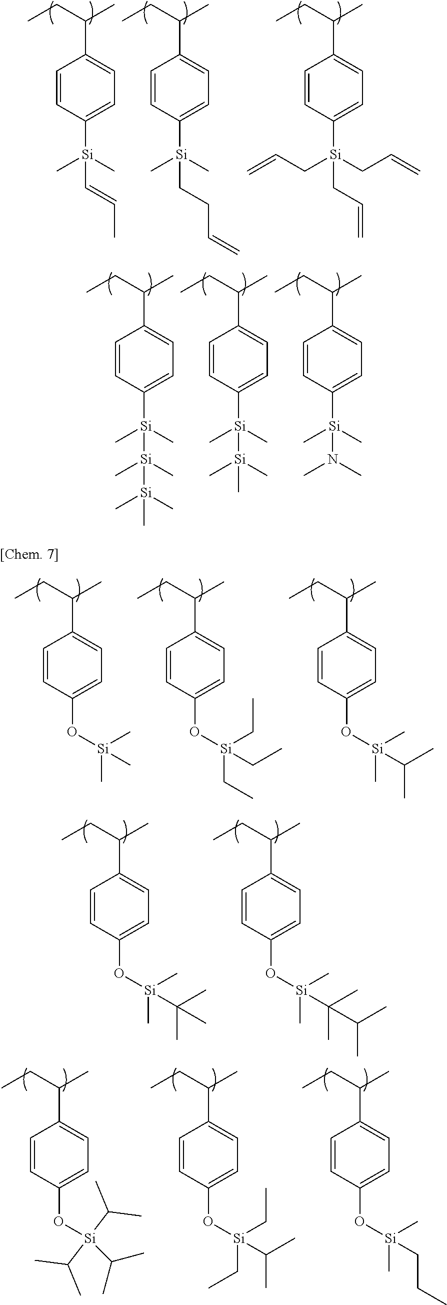

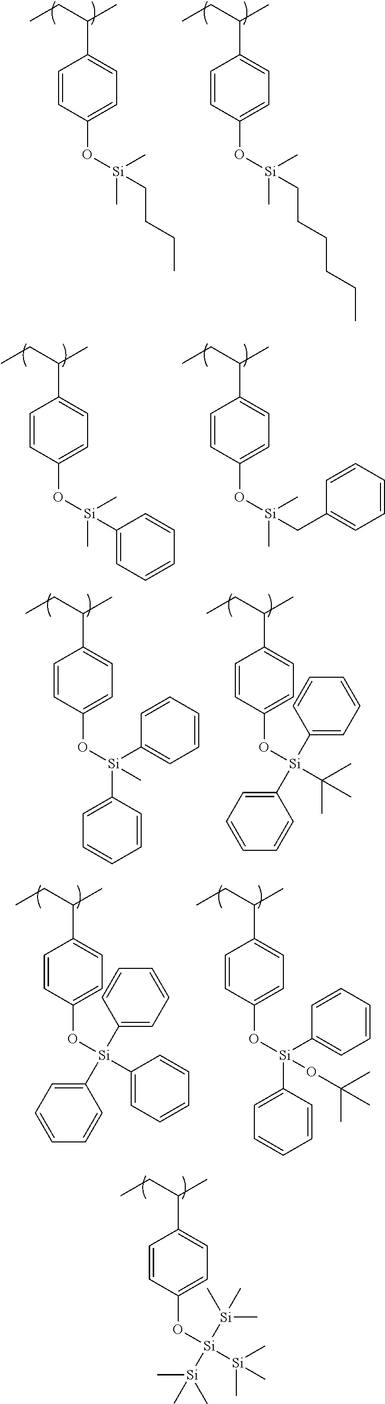

(Constituent Unit Represented by Formula (a2-2))

The block (A2) is preferably composed of a random copolymer having a structure in which a constituent unit represented by the formula (a2-1) and a constituent unit represented by the following formula (a2-2) are randomly arranged.

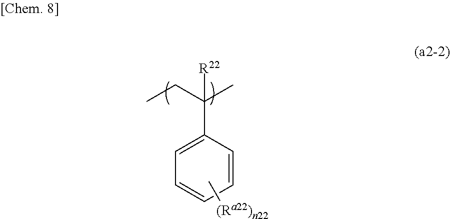

In the formula (a2-2), R^{a22} is an alkyl group, n22 is an integer of 0 or more and 5 or less; and R²² is a hydrogen atom, an alkyl group having 1 or more and 5 or less carbon atoms, or a halogenated alkyl group having 1 or more and 5 or less carbon atoms.

When n22 is an integer of 2 or more, a plurality of R^{a22}s may be same as or different from each other.

Examples of the alkyl group as R^{a22} may be the same as those listed for the alkyl group as R^{a1}.

n22 is preferably 0 or 1, and more preferably 0.

Examples of the alkyl group having 1 or more and 5 or less carbon atoms and the halogenated alkyl group having 1 or more and 5 or less carbon atoms as R²² may be the same as those listed for these groups as R¹. R²² is preferably a hydrogen atom or an alkyl group having 1 or more and 5 or less carbon atoms, more preferably a hydrogen atom or a methyl group, and further preferably a hydrogen atom.

### [Block (A3)]

The block (A3) is composed of a random copolymer having a structure in which a constituent unit represented by the following formula (a3-1) and a constituent unit represented by the following formula (a3-2) are randomly arranged. Since the block (A3) has the constituent unit represented by the formula (a3-1) in addition to the constituent unit represented by the formula (a3-2), the interaction parameter of the block copolymer (A) can be increased, and a phase-separated structure having an excellent vertical orientation can be formed.

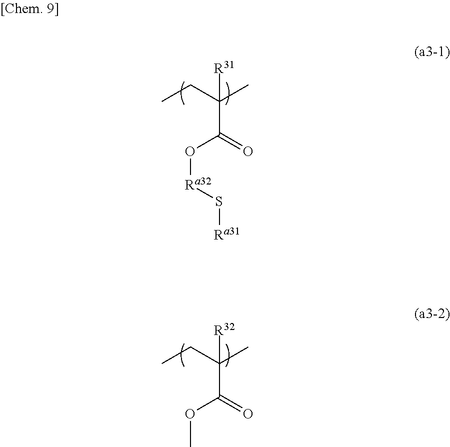

In the formula (a3-1), R^{a31} is an alkyl group which may have a silyl group, a fluorine atom, a carboxy group, an amino group, a hydroxy group, or a phosphoric acid group, and R^{a32} is an alkylene group which may have a hydroxy group, and in the formulas (a3-1) and (a3-2), R³¹ and R³² are each independently a hydrogen atom, an alkyl group having 1 or more and 5 or less carbon atoms, or a halogenated alkyl group having 1 or more and 5 or less carbon atoms.
(Constituent Unit Represented by Formula (a3-1))

The number of carbon atoms in the alkyl group as R^{a31} is preferably 1 or more and 20 or less, more preferably 1 or more and 10 or less, and further preferably 1 or more and 5 or less. The alkyl group as R^{a31} may be linear or branched, and is preferably linear. Examples of the alkyl group as R^{a31} include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group. Among them, a methyl group, an ethyl group, an n-propyl group, an n-butyl group, an n-pentyl group, an n-hexyl group, an n-heptyl group, or an n-octyl group is preferred, and a methyl group, an ethyl group, or an n-propyl group is more preferred.

When the alkyl group as R^{a31} has a silyl group, a fluorine atom, a carboxy group, an amino group, a hydroxy group, or a phosphoric acid group, the silyl group and others are a substituent that substitutes a hydrogen atom of the alkyl group. The number of hydrogen atoms to be substituted may be 1 or more and 5 or less, or 1 or more and 3 or less. Examples of the silyl group that may be included in the alkyl group as R^{a31} include an alkylsilyl group such as a monoalkylsilyl group, a dialkylsilyl group, and a trialkylsilyl group. Among them, the trialkylsilyl group is preferred. The number of carbon atoms in the alkyl group of the alkylsilyl group is preferably 1 or more and 5 or less, and more preferably 1 or more and 3 or less. Examples of the alkyl group in the alkylsilyl group include a methyl group, an ethyl group, an n-propyl group, an isopropyl group, an n-butyl group, an isobutyl group, a sec-butyl group, a tert-butyl group, and an n-pentyl group. Among them, a methyl group or an ethyl group is preferred, and a methyl group is more preferred.

The number of carbon atoms in the alkylene group as R^{a32} is preferably 2 or more, and more preferably 3 or more. In addition, the number of carbon atoms in the alkylene group is preferably 10 or less, and, from the viewpoint of the phase separation performance, more preferably 8 or less, further preferably 5 or less, and particularly preferably 4 or less. The number of carbon atoms in the alkylene group is most preferably 3. The alkylene group as R^{a32} may be linear or branched, and is preferably linear.

When the alkylene group as R^{a32} has a hydroxy group, the number of hydroxy groups is preferably 1 or more and 3 or less, more preferably 1 or 2, and further preferably 1.

Examples of the alkyl group having 1 or more and 5 or less carbon atoms and the halogenated alkyl group having 1 or more and 5 or less carbon atoms as R³¹ may be the same as those listed for these groups as R¹. R³¹ is preferably a hydrogen atom or an alkyl group having 1 or more and 5 or less carbon atoms, more preferably a hydrogen atom or a methyl group, and further preferably a methyl group.

(Constituent Unit Represented by Formula (a3-2))

Examples of the alkyl group having 1 or more and 5 or less carbon atoms and the halogenated alkyl group having 1 or more and 5 or less carbon atoms as R³² may be the same as those listed for these groups as R¹. R³² is preferably a hydrogen atom or an alkyl group having 1 or more and 5 or less carbon atoms, more preferably a hydrogen atom or a methyl group, and further preferably a methyl group.

In the block copolymer (A), the ratio of the number of moles of the constituent unit of the block (A1) to a total of the number of moles of the constituent unit of the block (A1), the number of moles of the constituent unit of the block (A2), and the number of moles of the constituent unit of the block (A3) is preferably 10 mol % or more and 70 mol % or less, more preferably 20 mol % or more and 60 mol % or less, and further preferably 30 mol % or more and 50 mol % or less.

In the block copolymer (A), the ratio of the number of moles of the constituent unit of the block (A2) to a total of the number of moles of the constituent unit of the block (A1), the number of moles of the constituent unit of the block (A2), and the number of moles of the constituent unit of the block (A3) is preferably 5 mol % or more and 30 mol % or less, more preferably 8 mol % or more and 25 mol % or less, and further preferably 10 mol % or more and 20 mol % or less.

In the block copolymer (A), the ratio of the number of moles of the constituent unit of the block (A3) to a total of the number of moles of the constituent unit of the block (A1), the number of moles of the constituent unit of the block (A2), and the number of moles of the constituent unit of the block (A3) is preferably 20 mol % or more and 80 mol % or less, more preferably 30 mol % or more and 70 mol % or less, and further preferably 40 mol % or more and 60 mol % or less.

In the block copolymer (A), the ratio of a total of the number of moles of the constituent unit of the block (A1) and the number of moles of the constituent unit of the block (A2) to a total of the number of moles of the constituent unit of the block (A1), the number of moles of the constituent unit of the block (A2), and the number of moles of the constituent unit of the block (A3) is preferably 20 mol % or more and 80 mol % or less, more preferably 30 mol % or more and 70 mol % or less, and further preferably 40 mol % or more and 60 mol % or less.

In the block (A2), the ratio of the number of moles of the constituent unit represented by the formula (a2-1) to a total of the number of moles of the constituent unit represented by the formula (a2-1) and the number of moles of the constituent unit represented by the formula (a2-2) is preferably 2 mol % or more and 50 mol % or less, more preferably 4 mol % or more and 40 mol % or less, and further preferably 6 mol % or more and 30 mol % or less.

In the block (A3), the ratio of the number of moles of the constituent unit represented by the formula (a3-1) to a total of the number of moles of the constituent unit represented by the formula (a3-1) and the number of moles of the constituent unit represented by the formula (a3-2) is preferably 2 mol % or more and 50 mol % or less, more preferably 4 mol % or more and 40 mol % or less, and further preferably 6 mol % or more and 30 mol % or less.

The block copolymer (A) may have another block in addition to the block (A1), the block (A2), and the block (A3). In a preferred embodiment, the block copolymer (A) is a triblock copolymer composed of the block (A1), the block (A2), and the block (A3).

A number average molecular weight (Mn) of the block copolymer (A) is not particularly limited, and is preferably 5,000 or more and 100,000 or less, more preferably 10,000 or more and 60,000 or less, and further preferably 15,000 or more and 40,000 or less. A polydispersity index (PDI) (Mw/Mn) of the block copolymer (A) is preferably 1.0 or more and 1.5 or less, more preferably 1.0 or more and 1.4 or less, and further preferably 1.0 or more and 1.3 or less. In this specification, the terms “number average molecular weight” (Mn) and “weight average molecular weight” (Mw) mean a number average molecular weight and a weight average molecular weight, respectively, in terms of standard polystyrene as measured by gel penetration chromatography (GPC), unless otherwise specified. When a value of Mn or Mw is described preceding a unit (g mol-1), the value represents a molar mass.

A method for producing the block copolymer is not particularly limited, and the block copolymer can be produced by any known method. For example, the block copolymer can be produced by a production method utilizing the method described in Japanese Unexamined Patent Application, Publication No. 2022-20519.

### <Organic Solvent>

The resin composition for forming a phase-separated structure preferably contains an organic solvent. Any organic solvent may be used as the organic solvent as long as the organic solvent can dissolve each component to be used and form a homogeneous solution. In the related art, any organic solvent selected from known organic solvents as a solvent for a composition including a resin as a main component may be used.

Examples of the organic solvent include a lactone such as γ-butyrolactone; a ketone such as acetone, methyl ethyl ketone, cyclohexanone, methyl n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of the polyhydric alcohol or a derivative of a polyhydric alcohol having an ether bond, such as a monoalkyl ether of the polyhydric alcohol or the polyhydric alcohol monoacetate, such as a monomethyl ether, a monoethyl ether, a monopropyl ether, or a monobutyl ether of the polyhydric alcohol or the polyhydric alcohol monoacetate, or a monophenyl ether of the polyhydric alcohol or the polyhydric alcohol monoacetate [among them, propylene glycol monomethyl ether acetate (PGMEA) or propylene glycol monomethyl ether (PGME) is preferred]; a cyclic ether such as dioxane, or an ester other than a polyhydric alcohol monoacetate and a derivative of the polyhydric alcohols described above, such as methyl lactate, ethyl lactate (EL), methyl acetate, ethyl acetate, butyl acetate, methyl pyruvate, ethyl pyruvate, methyl methoxypropionate, or ethyl ethoxypropionate; and an aromatic organic solvent such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, or mesitylene. The organic solvent may be used alone, or two or more thereof may be used as a mixed solvent. Among them, propylene glycol monomethyl ether acetate (PGMEA), propylene glycol monomethyl ether (PGME), cyclohexanone, or ethyl lactate (EL) is preferred.

The concentration of the organic solvent is determined appropriately according to a coating film thickness such that the resin composition for forming a phase-separated structure can be applied. The organic solvent is generally used such that a solid content concentration of the resin composition for forming a phase-separated structure is in a range of 0.2% by mass or more and 70% by mass or less, and preferably 0.2% by mass or more and 50% by mass or less.

### <Other Component>

The resin composition for forming a phase-separated structure may contain a component other than the block copolymer (A) and the organic solvent. Examples of other component include another resin such as a homopolymer, a surfactant, a dissolution inhibiting agent, a plasticizing agent, a stabilizing agent, a coloring agent, an anti-halation agent, a dye, a sensitizing agent, a base proliferating agent, and a basic compound.

### <<Method for Producing Structure Having Phase-Separated Structure>>

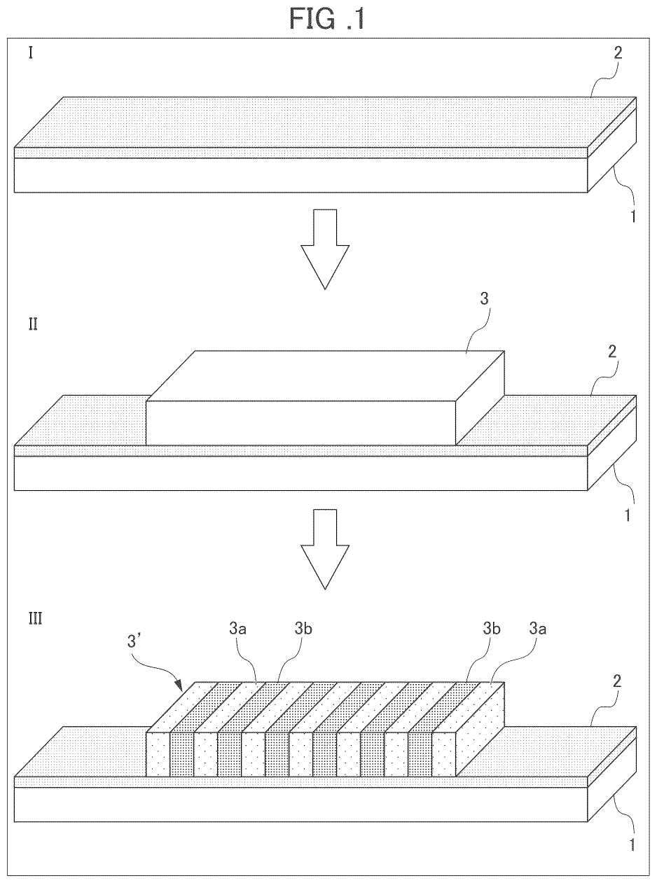

A method for producing a structure having a phase-separated structure according to a second aspect includes applying the resin composition for forming a phase-separated structure as described in the first aspect on a support to form a layer containing the block copolymer (hereinafter, referred to as “Step (i)”), and phase-separating the layer containing the block copolymer (hereinafter, referred to as “Step (ii)”). Hereinafter, such a method for producing a structure having a phase-separated structure will be described in detail with reference to FIG. 1. However, the method for producing a structure having a phase-separated structure is not limited to the specific aspect shown in FIG. 1.

FIG. 1 shows an exemplary embodiment of the method for producing a structure having a phase-separated structure. In the embodiment shown in FIG. 1, an undercoat agent is first applied on a support 1 to form an undercoat agent layer 2 (FIG. 1 (I)). Next, the resin composition for forming a phase-separated structure is applied on the undercoat agent layer 2 to form a layer (BCP layer) 3 containing a block copolymer (FIG. 1 (II), the above is Step (i)). Then, the resultant is annealed by heating to phase-separate the BCP layer 3 into phases 3a and phases 3b (FIG. 1 (III), Step (ii)). According to such a production method of the embodiment, that is, the production method including Step (i) and Step (ii), a structure 3′ having a phase-separated structure is produced on the support 1 on which the undercoat agent layer 2 is formed.

<Step (i)>

In Step (i), the resin composition for forming a phase-separated structure is applied on the support 1 to form the BCP layer 3. In the embodiment shown in FIG. 1, the undercoat agent is first applied on the support 1 to form the undercoat agent layer 2. By providing the undercoat agent layer 2 on the support 1, a hydrophilic-hydrophobic balance can be achieved between a surface of the support 1 and the layer (BCP layer) 3 containing the block copolymer. That is, when the undercoat agent layer 2 contains a resin component having a constituent unit constituting any block of the block copolymer, adhesion between a phase constituted by the block in the BCP layer 3 and the support 1 is improved. Accordingly, a phase-separated structure oriented in a direction perpendicular to the surface of the support 1 is easily formed by the phase separation of the BCP layer 3.

### Undercoat Agent:

A resin composition can be used as the undercoat agent. The resin composition for the undercoat agent can be appropriately selected from known resin compositions in the related art that is to be used for forming a thin film, depending on a type of a block constituting a block copolymer. The resin composition for the undercoat agent may be, for example, a thermopolymerizable resin composition or may be a photosensitive resin composition such as a positive-type resist composition or a negative-type resist composition. Furthermore, a non-polymerized film formed by applying a compound serving as a surface treating agent may be used as the undercoat agent layer. For example, a siloxane-based organic monolayer formed by applying phenethyltrichlorosilane, octadecyltrichlorosilane, hexamethyldisilazane, or the like as a surface treating agent can also be suitably used as the undercoat agent layer.

Examples of such a resin composition include a resin composition containing a resin having all constituent units constituting the respective blocks constituting the block polymer, and a resin composition containing a resin having all constituent units having high affinity for the respective blocks constituting the block copolymer. For example, a composition containing a resin having both styrene and methyl methacrylate as a constituent unit or a compound or a composition including both a moiety having a high affinity with styrene such as an aromatic ring and a moiety having a high affinity with methyl methacrylate (e.g., a highly polar functional group) is preferably used as the resin composition for the undercoat agent. Examples of the resin having both styrene and methyl methacrylate as a constituent unit include a random copolymer of styrene and methyl methacrylate, or an alternating polymer of styrene and methyl methacrylate (polymer in which each monomer is alternately copolymerized). Furthermore, examples of the composition including both a moiety having a high affinity with styrene and a moiety having a high affinity with methyl methacrylate include a composition containing a resin obtained by polymerizing at least a monomer having an aromatic ring and a monomer having a highly polar functional group as monomers. Examples of the monomer having an aromatic ring include a monomer having an aryl group in which one hydrogen atom is removed from an aromatic hydrocarbon ring such as a phenyl group, a biphenyl group, a fluorenyl group, a naphthyl group, an anthryl group, or a phenanthryl group; or a heteroaryl group in which a portion of carbon atoms constituting a ring on any of the above-mentioned groups is substituted with a heteroatom such as an oxygen atom, a sulfur atom, or a nitrogen atom. Furthermore, examples of the monomer having a highly polar functional group include a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Furthermore, examples of the compound including both a moiety having a high affinity with styrene and a moiety having a high affinity with methyl methacrylate include a compound including both an aryl group and a highly polar functional group such as phenethyltrichlorosilane; or a compound including both an alkyl group and a highly polar functional group such as an alkylsilane compound.

The resin composition for the undercoat agent can be produced by dissolving the above-mentioned resin in a solvent. Such a solvent may be any solvent as long as the solvent can dissolve a component to be used and form a homogeneous solution. For example, the same organic solvent component as one exemplified in the above-mentioned description for the resin composition for forming a phase-separated structure may be used.

A type of the support 1 is not particularly limited as long as the resin composition can be applied on the surface of the support 1. Examples thereof include a substrate made of an inorganic material such as a silicon, a metal (e.g., copper, chromium, iron, or aluminum), glass, titanium oxide, silica, or mica; a substrate made of an oxide such as SiO₂; a substrate made of a nitride such as SiN; a substrate made of an oxynitride such as SiON; or a substrate made of an organic material such as an acryl resin, polystyrene, cellulose, cellulose acetate, or a phenolic resin. Among them, a silicon substrate (Si substrate) or a metal substrate is suitable, a Si substrate or a copper substrate (Cu substrate) is more suitable, and a Si substrate is particularly suitable. A size or a shape of the support 1 is not particularly limited. The support 1 does not necessarily have a smooth surface, and substrates having various shapes can be appropriately selected. For example, a substrate having a curved surface, a flat plate having an uneven surface, or a flaky substrate may be used.

An inorganic and/or organic film may be provided on the surface of the support 1. Examples of the inorganic film include an inorganic antireflection film (inorganic BARC). Examples of the organic film include an organic antireflection film (organic BARC). The inorganic film can be formed, for example, by applying an inorganic antireflection film composition such as a silicon-based material on a support and baking the resultant. The organic film can be formed, for example, by applying a material for forming an organic film in which a resin component or the like constituting the organic film is dissolved in an organic solvent on a substrate using a spinner or the like, and baking the resultant under heating conditions of preferably 200° C. or higher and 300° C. or lower for preferably 30 seconds or more and 300 seconds or less and more preferably for 60 seconds or more and 180 seconds or less. This material for forming an organic film does not necessarily need sensitivity to light or electron beams unlike a resist film, and may or may not have the sensitivity. Specifically, a resist or a resin generally used for producing a semiconductor element or a liquid crystal display element may be used. Furthermore, the material for forming an organic film is preferably a material capable of forming an organic film that can be subjected to etching, particularly dry-etching so that an organic film pattern may be formed by etching the organic film using a pattern formed by processing the BCP layer 3 and made of the block copolymer and transferring the pattern to the organic film. Among them, a material capable of forming an organic film that can be subjected to etching such as oxygen plasma etching is preferably used. Such a material for forming an organic film may be a material used for forming an organic film such as organic BARC in the related art. Examples thereof include ARC series manufactured by Nissan Chemical Corporation, AR series manufactured by Rohm and Haas Japan Ltd., or SWK series manufactured by TOKYO OHKA KOGYO CO., LTD.

A method for forming the undercoat agent layer 2 by applying the undercoat agent on the support 1 is not particularly limited and may be any known method in the related art. For example, the undercoat agent layer 2 can be formed by applying the undercoat agent on the support 1 using a known method in the related art such as a spin coating or use of a spinner to form a coated film, and drying the coated film. A method for drying the coated film is not limited as long as a solvent contained in the undercoat agent can be volatilized, and, for example, baking may be used. In this case, a baking temperature is preferably 80° C. or higher and 300° C. or lower, more preferably 180° C. or higher and 270° C. or lower, and further preferably 220° C. or higher and 250° C. or lower. A baking time is preferably 30 seconds or more and 600 seconds or less and more preferably 60 seconds or more and 600 seconds or less. A thickness of the undercoat agent layer 2 after drying the coated film is preferably about 5 nm or more and 100 nm or less.

The surface of the support 1 may be previously cleaned before the undercoat agent layer 2 is formed on the support 1. Cleaning of the surface of the support 1 improves coatability of the undercoat agent. A known cleaning treatment method in the related art can be used, and examples thereof include an oxygen plasma treatment, an ozone oxidation treatment, an acid alkali treatment, or a chemical modification treatment.

After the undercoat agent layer 2 is formed, the undercoat agent layer 2 may be rinsed with a rinsing liquid such as a solvent, as necessary. Since an uncrosslinked portion or the like of the undercoat agent layer 2 is removed by rinsing, affinity with at least one block constituting a block copolymer is improved, and thus, a phase-separated structure having a cylindrical structure oriented in a direction perpendicular to the surface of the support 1 is likely to be formed. The rinsing liquid may be any liquid as long as the liquid can dissolve the uncrosslinked portion and, for example, a solvent such as propylene glycol monomethyl ether acetate (PGMEA), propylene glycol monomethyl ether (PGME), or ethyl lactate (EL), or a commercially available thinner liquid may be used. After the cleaning, post-baking may be performed in order to volatilize the rinsing liquid. A temperature condition during the post-baking is preferably 80° C. or higher and 300° C. or lower and more preferably 100° C. or higher and 270° C. or lower. A baking time is preferably 30 seconds or more and 500 seconds or less and more preferably 60 seconds or more and 240 seconds or less. A thickness of the undercoat agent layer 2 after such post-baking is preferably about 1 nm or more and 10 nm or less and more preferably about 2 nm or more and 7 nm or less.

Next, the layer (BCP layer) 3 containing the block copolymer is formed on the undercoat agent layer 2. A method of forming the BCP layer 3 on the undercoat agent layer 2 is not particularly limited, and, for example, may be a method including applying the resin composition for forming a phase-separated structure according to the above-mentioned embodiment on the undercoat agent layer 2 by a known method in the related art such as spin coating or use of a spinner to form a coated film and drying the coated film.

A thickness of the BCP layer 3 need only be sufficient for phase separation to occur. Considering a type of the support 1, or a size of a structural period or uniformity of a nanostructure of the phase-separated structure to be formed, or the like, the thickness is preferably 10 nm or more and 100 nm or less and more preferably 20 nm or more and 80 nm or less.

<Step (ii)>

In Step (ii), the BCP layer 3 formed on the support 1 is phase-separated. After Step (i), the support 1 is annealed by heating to form a phase-separated structure in which at least a part of the surface of the support 1 is exposed by selective removal of the block copolymer. That is, the structure 3′ having the phase-separated structure in which the phase 3a and the phase 3b are phase-separated is produced on the support 1. A temperature condition during the annealing treatment is preferably a glass transition temperature of a block copolymer used or higher and lower than its thermal decomposition temperature. For example, when the block copolymer is a polystyrene-polymethyl methacrylate (PS-PMMA) block copolymer (mass average molecular weight: 5000 or more and 100000 or less), the temperature condition is preferably 180° C. or higher and 270° C. or lower. A heating time is preferably 30 seconds or more and 3600 seconds or less. The annealing treatment is preferably performed in a less reactive gas such as nitrogen.

### <Optional Step>

The method for producing a structure having a phase-separated structure is not limited to the above-mentioned embodiment and may include a step other than Step (i) and Step (ii) (optional step).

Such an optional step includes a step of selectively removing a phase constituted by at least one of the respective blocks constituting the block copolymer from the BCP layer 3 (hereinafter, referred to as “Step (iii)”), a guide pattern formation step, or the like.

Regarding Step (iii)

In Step (iii), a phase constituted by at least one of the respective blocks constituting the block copolymer is selectively removed from the BCP layer formed on the undercoat agent layer 2. This results in formation of a fine pattern (polymer nanostructure).

Examples of the method for selectively removing the phase constituted by the block include a method for subjecting the BCP layer to an oxygen plasma treatment or a method for subjecting the BCP layer to a hydrogen plasma treatment. For example, when the BCP layer containing the block copolymer (A) is phase-separated and then the BCP layer is subjected to an oxygen plasma treatment, a hydrogen plasma treatment, or the like, a phase constituted by the blocks (A1) and (A2) is not selectively removed, but a phase constituted by the block (A3) is selectively removed.

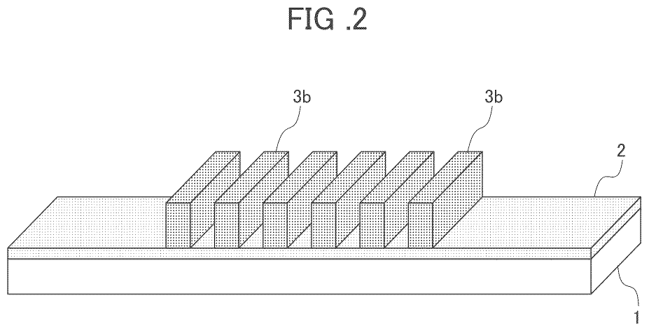

FIG. 2 shows an exemplary embodiment of Step (iii). In the embodiment shown in FIG. 2, the structure 3′ produced on the support 1 in Step (ii) is subjected to an oxygen plasma treatment to selectively remove the phases 3a, resulting in formation of a pattern (polymer nanostructure) constituted by the phases 3b apart from each other. In this case, the phase 3b is the phase constituted by the blocks (A1) and (A2), and the phase 3a is the phase constituted by the block (A3).

The support 1 with a pattern formed by phase separation of the BCP layer 3 made of the block copolymer as described above can be used as is, or a shape of the pattern (polymer nanostructure) on the support 1 can be changed by further heating. A temperature condition during the heating is preferably a glass transition temperature of the block copolymer used or higher and lower than its thermal decomposition temperature. The heating is preferably performed in a less reactive gas such as nitrogen.

### Regarding Guide Pattern Formation Step

The method for producing a structure having a phase-separated structure may include a step of providing a guide pattern on the undercoat agent layer (guide pattern formation step) between Step (i) and Step (ii) described above. This allows an array structure of the phase-separated structure to be controlled. For example, even for a block copolymer from which a fingerprint-shaped phase-separated structure is randomly formed when a guide pattern is not provided, a groove structure of a resist film can be provided on a surface of the undercoat agent layer to obtain a phase-separated structure oriented along the groove. According to this principle, a guide pattern may be provided on the undercoat agent layer 2. Further, in the case where a surface of the guide pattern has an affinity with any of blocks constituting the above-mentioned block copolymer, a phase-separated structure having a cylindrical structure oriented in a direction perpendicular to the surface of the support is likely to be formed.

The guide pattern can be formed using, for example, a resist composition. For the resist composition for forming the guide pattern, a resist composition having an affinity with any of blocks constituting the above block copolymer can be appropriately selected from resist compositions to be generally used for forming a resist pattern or a modified product thereof. The resist composition may be either a positive-type resist composition from which a positive-type pattern is formed, that is, an exposed area of a resist film is dissolved and removed or a negative-type resist composition from which a negative-type pattern is formed, that is, an unexposed area of a resist film is dissolved and removed, but a negative-type resist composition is preferred. The negative-type resist composition is preferably a resist composition that contains, for example, an acid generating agent and a base material component having a solubility in an organic solvent-containing developing solution that decreases under action of an acid, the base material component containing a resin component that has a constituent unit degraded under action of an acid to have an increased polarity. After a BCP composition is poured onto the undercoat agent layer on which the guide pattern is formed, an annealing treatment is performed to cause phase separation. Therefore, a composition capable of forming a resist film having excellent solvent resistance and heat resistance is preferably used as the resist composition for forming the guide pattern.

As described above, the present inventors provide the following aspects (1) to (5).

(1) A resin composition for forming a phase-separated structure, the resin composition containing a block copolymer (A),
the block copolymer (A) having a block (A1), a block (A2), and a block (A3) in this order,
the block (A1) being composed of a polymer having a repeating structure of a constituent unit represented by the following formula (a1),
the block (A2) being composed of a polymer having a constituent unit represented by the following formula (a2-1), and
the block (A3) being composed of a random copolymer having a structure in which a constituent unit represented by the following formula (a3-1) and a constituent unit represented by the following formula (a3-2) are randomly arranged,

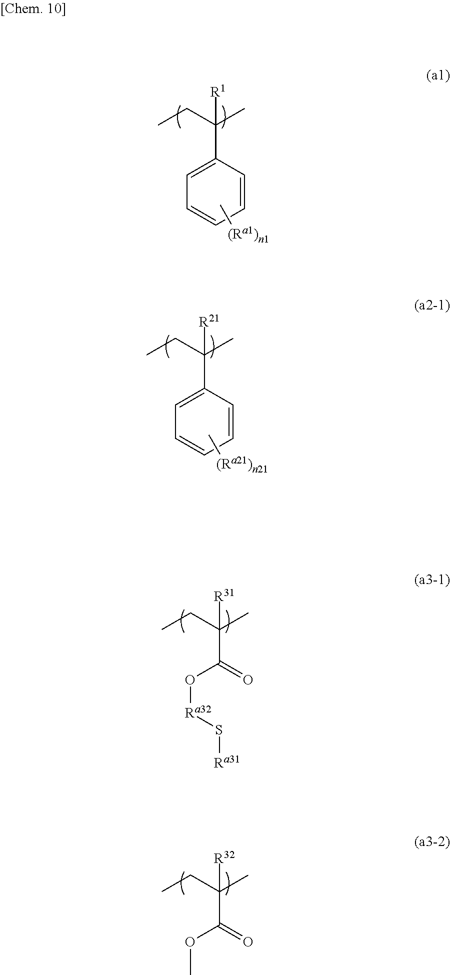

in which, in the formula (a1), R^{a1} is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which optionally has a silyl group, a fluorine atom, a carboxy group, an amino group, a hydroxy group, or a phosphoric acid group, and R^{a32} is an alkylene group which optionally has a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.

(2) The resin composition for forming a phase-separated structure according to aspect (1), in which the block (A2) is composed of a random copolymer having a structure in which the constituent unit represented by the formula (a2-1) and a constituent unit represented by the following formula (a2-2) are randomly arranged,

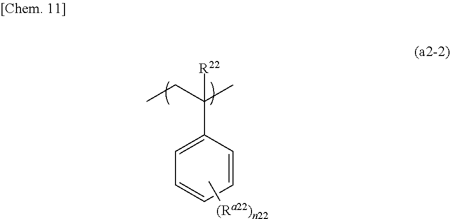

in which, in the formula (a2-2), R^{a22} is an alkyl group, n22 is an integer of 0 or more and 5 or less; and R²² is a hydrogen atom, an alkyl group having 1 or more and 5 or less carbon atoms, or a halogenated alkyl group having 1 or more and 5 or less carbon atoms.

(3) The resin composition for forming a phase-separated structure according to aspect (1) or (2), in which R^{a21} is a group represented by the following formula (a2-1-1),

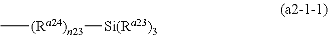

in which, in the formula (a2-1-1), each R^{a23} is independently an organic group, R^{a24} is an oxygen atom, or an alkylene group having 1 or more and 4 or less carbon atoms, and n23 is 0 or 1.

(4) A method for producing a structure having a phase-separated structure, the method including:
applying the resin composition for forming a phase-separated structure according to any one of aspects (1) to (3) on a support to form a layer containing the block copolymer; and
phase-separating the layer containing the block copolymer.

(5) A block copolymer having a block (A1), a block (A2), and a block (A3) in this order,
the block (A1) being composed of a polymer having a repeating structure of a constituent unit represented by the following formula (a1),
the block (A2) being composed of a polymer having a constituent unit represented by the following formula (a2-1),
the block (A3) being composed of a random copolymer having a structure in which a constituent unit represented by the following formula (a3-1) and a constituent unit represented by the following formula (a3-2) are randomly arranged,

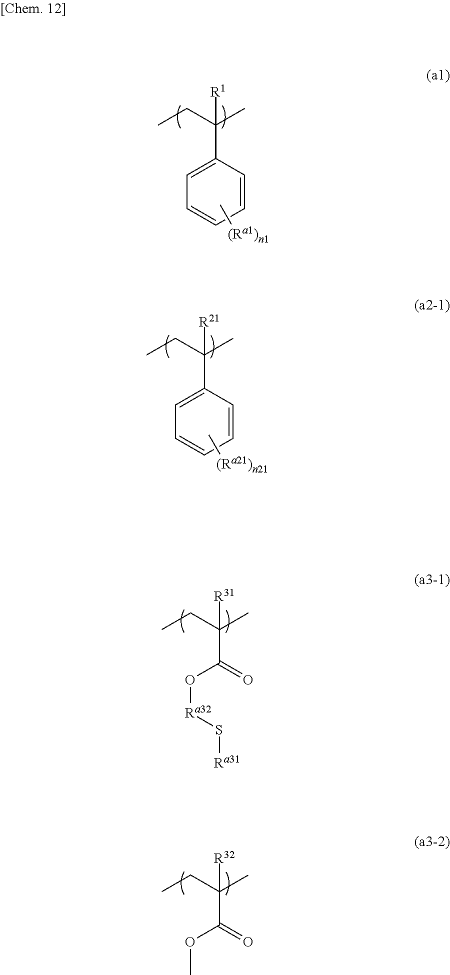

in which, in the formula (a1), R^{a1} is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which may have a silyl group, a fluorine atom, a carboxy group, an amino group, a hydroxy group, or a phosphoric acid group, and R^{a32} is an alkylene group which may have a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.

### Examples

Although the present invention will be described in more detail with reference to Examples, the present invention is not limited to Examples.

The following is an explanation of the block copolymers used in Example and Comparative Example.

BCP (1): a block copolymer represented by the following formula and having a block composed of polystyrene, a block composed of a random copolymer of styrene and 4-trimethylsilylstyrene, and a block composed of a random copolymer of 2-hydroxy-3-(2,2,2-trifluoroethylsulfanyl)propyl methacrylate and methyl methacrylate (Mn=26,200; PDI=1.02; l:m:n:o:p=33:12:1:4:50 (mol %))

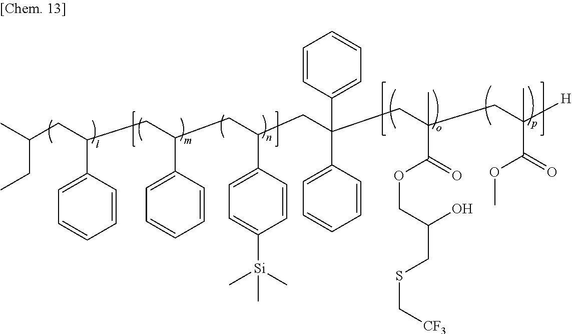

BCP (2): a block copolymer represented by the following formula and having a block composed of polystyrene and a block composed of polymethyl methacrylate (Mn=28,000; PDI=1.02; l:m=49:51 (mol %))

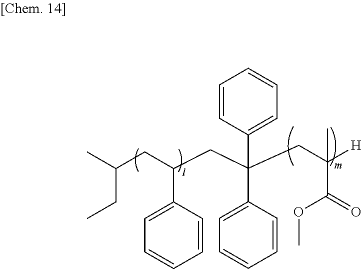

### <Synthesis of BCP (1)>

All anionic polymerizations were performed under an argon atmosphere. Thirty milliliter of tetrahydrofuran (THF) and lithium chloride (LiCl) (32.9 mg, 0.776 mmol) were transferred to a 100 mL Schlenk flask and cooled to −78° C. in a Coolnics bath. Sec-butyllithium (sec-BuLi) (1.05 M hexane/cyclohexane solution) was added to the Schlenk flask until the color of the solution turned to yellow. The Schlenk flask was removed from the Coolnics bath and warmed at room temperature until the solution became colorless. The Schlenk flask was again cooled to −78° C. in the Coolnics bath and sec-BuLi (0.115 mL, 0.150 mmol) was added as an initiator. Styrene (1.19 mL, 0.0104 mol) was added and the mixture was stirred for 30 minutes. As a result, a bright orange solution was obtained. A monomer mixture of styrene (0.313 mL, 0.00272 mol) and 4-trimethylsilylstyrene (TMSS) (0.0802 mL, 0.405 mmol) was added and the mixture was stirred for 30 minutes. The color of the solution was bright orange.

1,1-Diphenylethylene (DPE) (0.131 mL, 0.750 mmol) was added, and the color of the solution turned to deep red. After stirring for 30 minutes, a monomer mixture of methyl methacrylate (MMA) (11.50 mL, 0.0141 mol) and glycidyl methacrylate (GMA) (0.140 mL, 0.00106 mol) was added and the mixture was stirred for 30 minutes. The color of the solution turned from red to transparent. The polymerization was terminated by adding 10 mL of degassed methanol (MeOH) to the Schlenk flask as a terminator. The Schlenk flask was removed from the Coolnics bath, and the solution was poured into MeOH for reprecipitation. A precipitated solid was filtered and then dried under reduced pressure at 40° C. to obtain a white powder of a BCP precursor (1) (2.63 g, 88% yield). Mn and a polydispersity index (PDI=Mw/Mn) of the BCP precursor (1) measured by size-exclusion chromatography (SEC) were 26,000 and 1.03, respectively.

¹H NMR (400 MHz, CDCl₃, δ, ppm): 0.24 (s, Si—(CH₃)₃, PTMSS), 0.85 (s, α-CH₃, PGMA and PMMA), 1.02 (s, α-CH₃, PGMA and PMMA), 1.23 to 1.69 (br, backbone, —CH₂—CH—, PS and PTMSS), 1.74 to 2.27 (br, backbone, —CH₂—CH—, PS, br, backbone, —CH₂—C(CH₃)—, PGMA and PMMA), 2.64 (s, —CH₂—CH(CH₂)—O—, PGMA), 2.86 (s, —CH₂CH(CH₂)—O—, PGMA), 3.22 (s, —CH₂—CH(CH₂)—O—, PGMA), 3.60 (s, —OCH₃, PMMA), 3.78 (s, —(C═O)O—CH₂—, PGMA), 4.28 (d, —(C═O)O—CH₂—, PGMA), 6.22 to 6.85 (m, o-aromatic, PS and PTMSS), 6.85 to 7.42 (m, m-, p-aromatic, PS and PTMSS).

One gram of the BCP precursor (1) and THF (0.03 mol/L/GMA unit) were placed in a 200 mL glass tube, and then 1 wt % lithium hydroxide (LiOH) aqueous solution (0.3 mol equivalents of LiOH/GMA unit) and 2,2,2-trifluoroethanethiol (2 mol equivalents/GMA unit) were added to the glass tube. After stirring for 20 minutes at room temperature, the reactor was set to 40° C. and stirred for 3 hours to synthesize BCP (1). Residual reagents were removed by repeated precipitation of the synthesized BCP (1) with methanol several times. The product was dried overnight at room temperature under reduced pressure to obtain a white powder of the BCP (1). Mn and a polydispersity index (PDI=Mw/Mn) of the BCP (1) measured by size-exclusion chromatography (SEC) were 26,200 and 1.02, respectively.

1H NMR (400 MHz, CDCl₃, δ, ppm): 0.23 (s, Si—(CH₃)₃, PTMSS), 0.85 (s, α-CH₃, PHEMA and PMMA), 1.02 (s, α-CH₃, PHEMA and PMMA), 1.23 to 1.65 (br, backbone, —CH₂—CH—, PS and PTMSS), 1.68 to 2.26 (br, backbone, —CH₂—CH—, PS and PTMSS, br, backbone, —CH₂—C(CH₃)—, PHEMA and PMMA), 2.77 to 2.91 (s, CH(OH)—CH₂—S—, PHFMA), 3.17 to 3.37 (br, —S—CH₂—CF₃, PHFMA), 3.59 (s, —OCH₃, PMMA), 3.97 to 4.20 (br, —(C═O)O—CH₂—, PHFMA), 6.25 to 6.86 (m, o-aromatic, PS and PTMSS), 6.86 to 7.37 (m, m-, p-aromatic, PS and PTMSS).

### <Production of Structure Having Phase-Separated Structure>

### (Preparation of Resin Composition for Forming Phase-Separated Structure)

The block copolymer (BCP) of the type shown in Table 1 and propylene glycol monomethyl ether acetate were mixed for dissolution to prepare a resin composition for forming a phase-separated structure (solid content concentration: 1.5% by mass) in each example.

### (Preparation of Undercoat Agent)

To prepare an undercoat agent, a resin for undercoat agent NL-(1) was provided. NL-(1) is a random copolymer composed of styrene (St), methyl methacrylate (MMA) and (hydroxyethyl) methacrylate (HEMA). NL-(1) had a composition ratio (the ratio (mole ratio) of the respective constituent units in the structural formula) of St/MMA/HEMA=49/46/5, a number average molecular weight (Mn) of 28,000, and a Water Contact Angle (W.C.A.) of 75°. One hundred parts by mass of the resin for undercoat agent NL-(1) and 9900 parts by mass of propylene glycol monomethyl ether acetate were mixed for dissolution to prepare an undercoat agent NL-1.

### (Step (i))

A 12-inch silicon wafer substrate was provided as a support. The undercoat agent NL-1 was spin-coated on the silicon substrate, and then heated in an ambient atmosphere at 250° C. for 5 minutes. As a result, an undercoat agent layer composed of the resin for undercoat agent NL-(1) and having a thickness of 30 nm was formed on the surface of the substrate. Next, a rinsing liquid composed of propylene glycol monomethyl ether (PGME) and propylene glycol monomethyl ether acetate (PGMEA) (PGME/PGMEA=7/3) was used to rinse the undercoat agent layer. Then, the undercoat agent layer was heated at 100° C. for 1 minute to volatilize the rinsing liquid. Next, the resin composition for forming a phase-separated structure according to each Example was spin-coated on the substrate, and then pre-baked at 90° C. for 60 seconds in a nitrogen atmosphere to form a layer containing the block copolymer (BCP layer) having a thickness of 36 nm.

(Step (ii))

The BCP layer formed on the substrate was annealed at 240° C. for 5 minutes in a nitrogen atmosphere to form a phase-separated structure.

### [Evaluation of Vertical Orientation]

The surface (phase separation state) of the obtained substrate was observed with a length measuring SEM (scanning electron microscope, trade name: CG6300, manufactured by Hitachi High-Technologies Corporation). As a result of such observation, phase separation performance was evaluated based on the following evaluation criteria. The results are shown in Table 1 as “Vertical orientation”.

### (Evaluation Criteria)

A: vertical orientation was observed
B: vertical orientation was not observed
   [Evaluation of Structural Period (nm)]

A measurement was carried out on the surface (phase separation state) of the obtained substrate using a small angle X-ray scattering (SAXS) method, and the period (nm) of a structure resulted from each block copolymer was calculated from a primary scattering peak of an SAXS pattern curve. The results are shown in Table 1 as “Period (nm)”.

### [Evaluation of Etching Rate Ratio]

A resin composition containing the block copolymer (BCP) of the type shown Table 1 and a solvent was spin-coated on a silicon substrate to form a block copolymer layer (thickness of about 300 nm) as a sample for an etching rate measurement. The block copolymer layer was dry-plasma-etched using an oxygen plasma at 20 W and 20 sccm. A plasma etching apparatus manufactured by SATO VAC INC. was used as an apparatus for the etching. The thickness of the polymer layer was measured before and after the etching using F20-EXR manufactured by Filmetrics, Inc., and the measurements were compared to determine an etching rate. The ratio of the etching rate with respect to Comparative Example 1 was determined as an etching rate ratio. A smaller etching rate ratio means a higher difficulty to be removed by etching and more excellent etching resistance. The results are shown in Table 1 as “Etching rate ratio”.

TABLE 1

| | | | Comparative |
|---|---|---|---|
| | | Example 1 | Example 1 |
| BCP | Type | BCP (1) | BCP (2) |
| | Mn | 26,200 | 28,000 |
| Evaluation | Vertical orientation | A | B |
| | Period (nm) | 17.8 | — |
| | Etching rate ratio | 0.8 | 1 |

As shown in Table 1, when the composition according to Example, which contained the block copolymer (A), was used, then excellent vertical orientation and etching resistance were achieved. On the other hand, when the composition according to Comparative Example, which contained a block copolymer other than the block copolymer (A), was used, then inferior vertical orientation and etching resistance were observed.

What is claimed is:

1. A resin composition for forming a phase-separated structure, wherein the resin composition comprises a block copolymer (A),
the block copolymer (A) has a block (A1), a block (A2), and a block (A3) in this order,
the block (A1) comprises a polymer having a repeating structure of a constituent unit represented by formula (a1),
the block (A2) comprises a polymer having a constituent unit represented by formula (a2-1),
the block (A3) comprises a random copolymer having a structure in which a constituent unit represented by formula (a3-1) and a constituent unit represented by formula (a3-2) are randomly arranged, 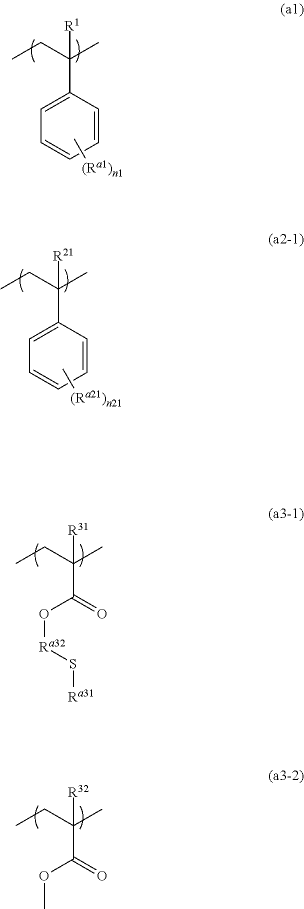
wherein, in the formula (a1), R^{a1} is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which optionally has a silyl group, a fluorine atom, a carboxy group, an amino group, a hydroxy group, or a phosphoric acid group, and R^{a32} is an alkylene group which optionally has a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.

2. The resin composition for forming a phase-separated structure according to claim 1, wherein the block (A2) comprises a random copolymer having a structure in which the constituent unit represented by the formula (a2-1) and a constituent unit represented by formula (a2-2) are randomly arranged, 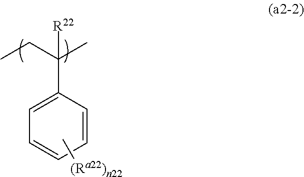
wherein, in the formula (a2-2), R^{a22} is an alkyl group, n22 is an integer of 0 or more and 5 or less; and R²² is a hydrogen atom, an alkyl group having 1 or more and 5 or less carbon atoms, or a halogenated alkyl group having 1 or more and 5 or less carbon atoms.

3. The resin composition for forming a phase-separated structure according to claim 1, wherein R^{a21} is a group represented by formula (a2-1-1), 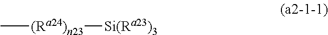
wherein, in the formula (a2-1-1), each R^{a23} is independently an organic group, R^{a24} is an oxygen atom, or an alkylene group having 1 or more and 4 or less carbon atoms, and n23 is 0 or 1.

4. A method for producing a structure having a phase-separated structure, the method comprising:
applying the resin composition for forming a phase-separated structure according to claim 1 on a support to form a layer comprising the block copolymer; and
phase-separating the layer comprising the block copolymer.

5. A block copolymer having a block (A1), a block (A2), and a block (A3) in this order,
wherein the block (A1) comprises a polymer having a repeating structure of a constituent unit represented by formula (a1),
the block (A2) being comprises a polymer having a constituent unit represented by formula (a2-1),
the block (A3) comprises a random copolymer having a structure in which a constituent unit represented by formula (a3-1) and a constituent unit represented by formula (a3-2) are randomly arranged, 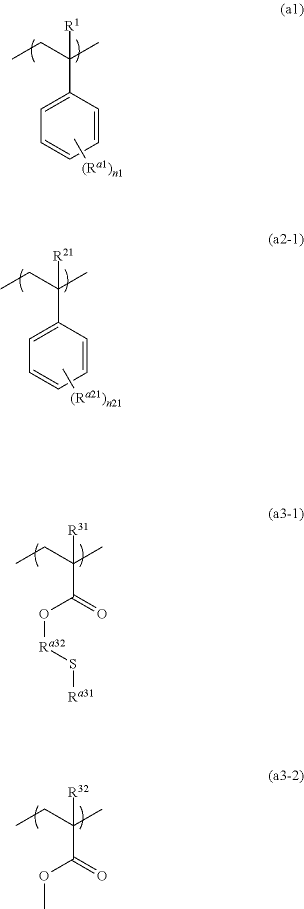
wherein, in the formula (a1), R^{a1} is an alkyl group, and n1 is an integer of 0 or more and 5 or less,
in the formula (a2-1), R^{a21} is a substituent having a silicon atom, and n21 is an integer of 1 or more and 5 or less,
in the formula (a3-1), R^{a31} is an alkyl group which optionally has a silyl group, a fluorine atom, a carboxy group, an amino group, a hydroxy group, or a phosphoric acid group; and R^{a32} is an alkylene group which optionally has a hydroxy group, and
in the formulas (a1), (a2-1), (a3-1), and (a3-2), R¹, R²¹, R³¹, and R³² are each independently a hydrogen atom, an alkyl group having 1 or more and 5 or less carbon atoms, or a halogenated alkyl group having 1 or more and 5 or less carbon atoms.
